(19) United States
(12) Patent Application Publication
(10) Pub. No.: US 2020/0050097 A1
(43) Pub. Date: Feb. 13, 2020

(54) NOVEL METHOD FOR FABRICATION OF EUV PHOTOMASK FIDUCIALS

(71) Applicant: Intel Corporation, Santa Clara, CA (US)

(72) Inventors: John MAGANA, San Jose, CA (US); Guojing ZHANG, Saratoga, CA (US)

(21) Appl. No.: 16/059,527

(22) Filed: Aug. 9, 2018

(51) Int. Cl. G03F 1/22; G03F 1/54; G03F 7/20

(52) U.S. Cl. CPC G03F 1/22; G03F 7/2002; G03F 1/54

(57) ABSTRACT

Embodiments disclosed herein include reticles for extreme ultraviolet (EUV) lithography and methods of forming such reticles. In an embodiment, the reticle may comprise a substrate and a mirror layer over the substrate. In an embodiment, the mirror layer includes alternating layers of a first mirror layer and a second mirror layer. In an embodiment, a fiducial may be formed into the mirror layer. In an embodiment, the fiducial comprises constituents of the first mirror layer and the second mirror layer. In an embodiment, an absorber layer may be formed over the mirror layer.

### TECHNICAL FIELD

Embodiments of the disclosure are in the field of semiconductor fabrication, and in particular, to reticles for extreme ultraviolet (EUV) lithography.

### BACKGROUND

For the past several decades, the scaling of features in integrated circuits has been a driving force behind an ever-growing semiconductor industry. Scaling to smaller and smaller features enables increased densities of functional units on the limited real estate of semiconductor chips. For example, shrinking transistor size allows for the incorporation of an increased number of memory devices on a chip, leading to the fabrication of products with increased capacity and functionality. The drive for ever-more capacity, however, is not without issue. Particularly, the critical dimensions are beginning to scale beyond the resolution capacity of existing lithographic patterning processes, such as deep ultraviolet (DUV) lithography.

Extreme ultraviolet (EUV) lithography allows for the critical dimension scaling to continue. However, the transition to EUV lithography has many engineering obstacles to overcome in order to be integrated into high volume manufacture operations. One particular obstacle that must be overcome is the need for high resolution blank-level fiducials to facilitate precise location of EUV blank multilayer defect coordinates required for defect mitigation schemes.

Currently, fiducials are fabricated into the substrate with a focused ion beam (FIB) or by patterning the fiducial into the multilayer mirror or overlying absorber material with traditional subtractive pattern processes. The use of FIB and subtractively manufactured fiducials has several limitations. One limitation is that such processes increase cost. In the case of FIB fiducials, the cost to manufacture blanks is increased since there is significant yield loss attributed to the FIB process. Particularly, FIB processes result in the generation of defects from overspray, which results in yield loss in the mask blank production factory. For subtractive processes, there needs to be at least one additional masking layer, which adds cost, complexity, increases throughput, and reduces mask final yield.

An additional limitation of FIB and subtractive processes is that the they do not have sufficient precision and/or accuracy for effective mitigation of relatively small (but still material) defects on the multilayer blank. Since both solutions typically rely on the determination of defect coordinates by locating a large multilayer defect (i.e., a defect that can be imaged through the absorber layer by means such as a 193 nm based mask pattern registration metrology tool or other imaging apparatus with stage accuracy of sufficient precision), accurate location of the defect's centroid is often subject to significant error. Furthermore, it is generally understood that mask blank suppliers will continue to reduce the defect density of relatively large defects (i.e., defects that are greater than 100 nm), and therefore, in the future there may be cases where no defects of sufficient size are present to by imaged for registration to fiducials fabricated with FIB and subtractive processes.

### BRIEF DESCRIPTION OF THE DRAWINGS

FIG. 1A is a cross-sectional illustration of femtosecond laser irradiation of an EUV reticle blank, in accordance with an embodiment.

FIG. 1B is a cross-sectional illustration of the reticle blank with a fiducial mark, in accordance with an embodiment.

FIG. 2A is a plan view illustration of an exemplary fiducial mark formed on an EUV reticle blank, in accordance with an embodiment.

FIG. 2B is a plot of the profile of the fiducial mark illustrated in FIG. 2A along line X-X′, in accordance with an embodiment.

FIG. 2C is a plot of the profile of the fiducial mark illustrated in FIG. 2A along line X-X′, in accordance with an additional embodiment.

FIG. 3A is a plan view illustration of an exemplary fiducial mark formed on an EUV reticle blank, in accordance with an embodiment.

FIG. 3B is an exemplary plot of the intensity recorded by an actinic radiation metrology tool along line X-X′ and line Y-Y′ in FIG. 3A, in accordance with an embodiment.

FIG. 4A is a plan view illustration of a reticle substrate, in accordance with an embodiment.

FIG. 4B is a plan view illustration after a mirror layer is formed over the substrate, in accordance with an embodiment.

FIG. 4C is a plan view illustration after a plurality of fiducials formed with a femtosecond laser are formed on the mirror layer, in accordance with an embodiment.

FIG. 4D is a plan view illustration after defects are registered and their position relative to the fiducials is determined, in accordance with an embodiment.

FIG. 4E is a plan view illustration after an absorber layer is disposed over the mirror layer, in accordance with an embodiment.

FIG. 4F is a plan view illustration after a masking pattern is formed over the absorber layer is patterned with a pattern that is shifted to a location that minimizes exposure of defects, in accordance with an embodiment.

FIG. 5A is a plan view illustration after fiducials formed with a femtosecond laser are formed over a mirror layer of an EUV reticle, in accordance with an embodiment.

FIG. 5B is a plan view illustration after the absorber layer is deposited over the mirror layer, in accordance with an embodiment.

FIG. 5C is a plan view illustration and a superimposition of the signal from an electron beam writer used to locate the fiducials, in accordance with an embodiment.

FIG. 5D is a plan view illustration after secondary fiducials are formed into the absorber layer over the first fiducials, in accordance with an embodiment.

FIG. 5E is a plan view illustration of the actinic imaging field of view centered on the secondary fiducials, in accordance with an embodiment.

FIG. 6 is a process flow diagram for using femtosecond laser generated fiducials in a defect mitigation scheme, in accordance with an embodiment.

### DESCRIPTION OF THE EMBODIMENTS

Embodiments described herein comprise reticles with femtosecond or lower time-scale laser generated fiducials and methods of forming such reticles. In the following description, numerous specific details are set forth, such as specific integration and material regimes, in order to provide a thorough understanding of embodiments of the present disclosure. It will be apparent to one skilled in the art that embodiments of the present disclosure may be practiced without these specific details. In other instances, well-known features, such as integrated circuit design layouts, are not described in detail in order to not unnecessarily obscure embodiments of the present disclosure. Furthermore, it is to be appreciated that the various embodiments shown in the Figures are illustrative representations and are not necessarily drawn to scale.

Certain terminology may also be used in the following description for the purpose of reference only, and thus are not intended to be limiting. For example, terms such as “upper”, “lower”, “above”, “below,” “bottom,” and “top” refer to directions in the drawings to which reference is made. Terms such as “front”, “back”, “rear”, and “side” describe the orientation and/or location of portions of the component within a consistent but arbitrary frame of reference which is made clear by reference to the text and the associated drawings describing the component under discussion. Such terminology may include the words specifically mentioned above, derivatives thereof, and words of similar import.

As noted above, fiducials formed with FIB and subtractive etching have significant drawbacks. Accordingly, embodiments disclosed herein include fiducials that are fabricated with ultra-short pulse laser processing. For example, “ultra-short” may refer to pulses that are in the femtosecond time-scale. The use of such fiducials provides for both ultrahigh accuracy mirror layer defect mitigation as well as a practical, fast methodology for quantification of mirror layer defect printability when used in conjunction with EUV actinic imaging metrology (AIMS). Additionally, fiducials formed in accordance with embodiments described herein may be employed for precise alignment and navigation to a given mirror layer defect during any repair process. Furthermore, precise alignment and navigation is particularly beneficial since some mirror layer defect modes (e.g., mirror layer phase defects with surface perturbations on the same order of the intrinsic mirror layer roughness) are not visible by typical means available in a repair tool (e.g., not visible via scanning electron microscopy (SEM) or atomic force microscopy (AFM)).

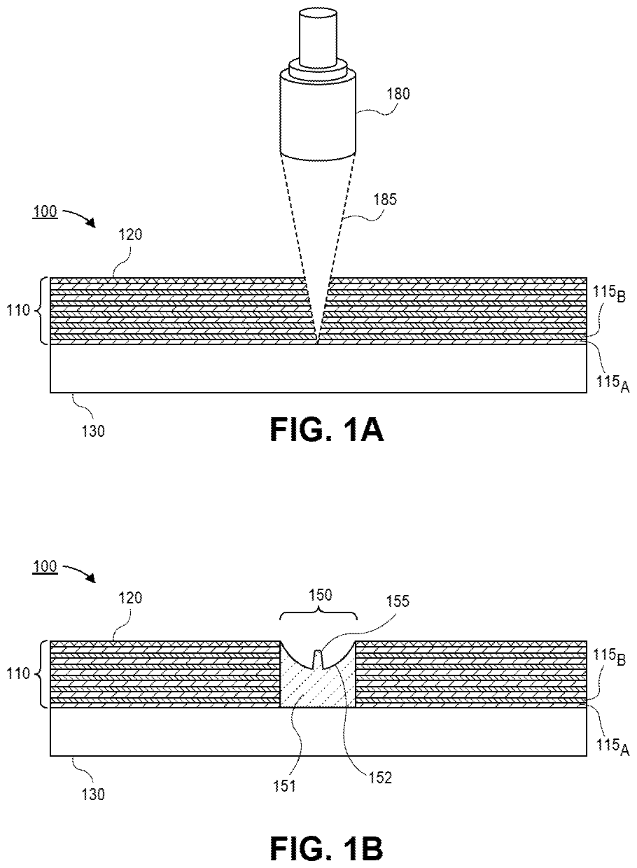

Referring now to FIG. 1A, a cross-sectional illustration of a EUV reticle blank 100 that is being irradiated with laser radiation 185 is shown, in accordance with an embodiment. In an embodiment, the EUV reticle may comprise an EUV Bragg mirror layer 120 formed over a substrate 130. In an embodiment, the substrate 130 may be quartz or another low thermal expansion coefficient material. In an embodiment, the mirror layer 120 may comprise a plurality of alternating first and second mirror layers 115_{A}/115_{B}. The mirror layer 110 is designed to reflect the EUV radiation (i.e., 13.5 nm). Common first and second mirror layers 115_{A}/115_{B} include molybdenum and silicon, but a plurality of other materials combinations can also be employed.

In an embodiment, there may be any number of alternating first and second mirror layers 115_{A}/115_{B}. For example, there may be 40 or more alternating layers in the mirror 110. In an embodiment, the first and second mirror layers 115_{A}/115_{B} may have distinct boundaries. For example, the first and second mirror layers 115_{A}/115_{B} may be referred to as a superlattice. In an embodiment, each individual layer 115_{A}/115_{B} may have a thickness that is approximately 10 nm or less. In an embodiment, the first mirror layers 115_{A} may have an average thickness that is approximately equal to an average thickness of the second mirror layers 115_{B}. In an alternative embodiment, the first mirror layers 115_{A} may have an average thickness that is different than an average thickness of the second mirror layers 115_{B}. In an embodiment, a capping layer 120 (e.g., ruthenium or a plurality of suitable elemental or compound materials) may be formed over the uppermost layer of the mirror layer 110.

In an embodiment, the EUV reticle 100 may be irradiated by laser radiation 185. For example, the laser radiation 185 may pass through a focusing objective lens 180. In the illustrated embodiment, the focal point of the laser radiation 185 is located on the surface of the substrate 130. However, the laser radiation 185 may be focused at any location between the substrate 130 and a top surface of the capping layer 120. Laser radiation can also be focused at a point above the plane of the capping layer. Focusing the laser radiation 185 at different locations may be desirable to provide fiducials with different geometries and topographies, as will be described in greater detail below.

In an embodiment, the laser radiation 185 is pulsed. In a particular embodiment, the laser radiation is pulsed at pulses with a duration in the femtosecond range. In an embodiment, the number of pulses used to form the fiducial and the power of the laser radiation used to form the fiducials may be varied to provide a fiducial with a desired topography.

In an embodiment, the irradiation of the EUV reticle 100 results in the modification of the mirror layer 110. Particularly, the irradiated areas undergo localized heating that results in inter-diffusion of the constituents of the first mirror layer 115_{A} and the second mirror layer 115_{B}. In some embodiments, one or both of the first mirror layer 115_{A} and 115_{B} in the irradiated region undergo a phase change (i.e., melting) that further increases the rate of diffusion between the first mirror layers 115_{A} and the second mirror layers 115_{B}.

Referring now to FIG. 1B, a cross-sectional illustration after a fiducial 150 is formed into the EUV reticle 100 is shown, in accordance with an embodiment. As shown, the fiducial 150 no longer comprises distinct alternating layers of the first mirror layer 115_{A} and the second mirror layer 115_{B}. In an embodiment, the fiducial 150 may comprise a substantially amorphous and homogeneous material 151. In an embodiment, the amorphous material 151 may comprise constituents of the first mirror layer 115_{A} and the second mirror layer 115_{B}. For example, the amorphous material 151 of the fiducial 150 may comprise an alloy of the constituents of the first mirror layer 115_{A} and the second mirror layer 115_{B}. In embodiments where the first mirror layer 115_{A} is molybdenum and the second mirror layer 115_{B} is silicon, the amorphous material may comprise a molybdenum silicide of stoichiometric or non-stoichiometric composition.

It is to be appreciated that the cross-section illustrated in FIG. 1B is simplified in order to not obscure embodiments described herein. For example, those skilled in the art will recognize that an abrupt boundary between the unaltered multilayer mirror 110 and the amorphous material 151 of the fiducial 150 may not be present. In embodiments, there may be a gradual change from the multilayer mirror 110 comprising a highly regular pattern of alternating first mirror layers 115_{A} and second mirror layers 115_{B} to the amorphous material 151.

In an embodiment, the fiducial 150 may comprise a recessed surface 152 relative to a top surface of the mirror 110 (or capping layer 120). In a particular embodiment, the recessed surface 152 may be non-planar (e.g., concave). It is to be appreciated that the recessed surface 152 may not be the result of ablating portions of the mirror layer 110. For example, embodiments may include no ablation of the mirror layer 110 or capping layer 120. Instead, the recessed surface 152 may be the result of a difference in the densities of the first and second mirror layers 115_{A}/115_{B} and the density of the amorphous material 151. For example, if the density of the amorphous material 151 is greater than an average density of the first mirror layer 115_{A} and the second mirror layer 115_{B}, then the amorphous material 151 may appear compacted relative to the unaltered mirror layer 120.

In some embodiments, the fiducial may also comprise a protrusion 155 that extends up from the recessed surface 152. In an embodiment, the protrusion 155 may be a needle-like protrusion (e.g., a protrusion that extends up from the recessed surface 152 and progressively narrows until it forms a point). In an embodiment, the protrusion 155 may be formed as a result of the processing used to form the fiducial 150. For example, fiducials formed with femtosecond laser irradiation that is at a relatively high energy or includes a relatively high number of pulses may organically form the protrusion 155 (i.e., the protrusion 155 may be formed without the need for additional patterning and/or deposition processes). For example, the protrusion 155 may be formed of the amorphous material 151. In an embodiment the protrusion 155 may be substantially centered in the fiducial 150. Accordingly, some embodiments may include a protrusion 155 that is particularly useful for precisely and accurately finding the center of the fiducial 150. In an embodiment, the point (e.g., local maximum) of the protrusion 155 may be substantially coplanar with a plane of the surrounding multilayer mirror. In other embodiments the point of the protrusion may be recessed below the plane of the multilayer mirror. For example, the point of the protrusion 155 may be approximately 50 nm below the plane of the surrounding multilayer mirror or less, approximately 25 nm below the plane of the surrounding multilayer mirror or less, approximately 10 nm below the plane of the surrounding multilayer mirror or less, or approximately 5 nm below the plane of the surrounding multilayer mirror or less.

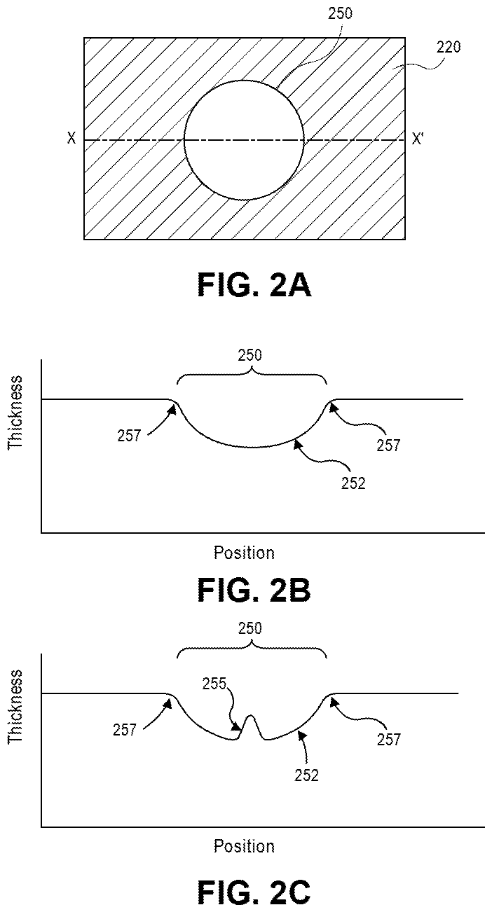

Referring now to FIG. 2A a, plan view illustration of a fiducial 250 is shown, in accordance to an embodiment. In an embodiment, the fiducial 250 may be substantially circular, though embodiments are not limited to circular fiducials. For example, elliptical fiducials may also be formed. Furthermore, an actinic image of the fiducial 250 illustrates a clear boundary between the fiducial 250 and the surrounding capping layer 220. For example, FIG. 2A may be representative of an actinic image (e.g., a 13.5 nm) image of a femtosecond fiducial 250. In an embodiment, the diameter of the fiducial 250 may be approximately 0.25 μm or larger, approximately 2 μm or larger, or approximately 5 μm or larger. It is to be appreciated that larger diameter fiducials 250 may be obtained by increasing the energy of the femtosecond laser and/or increasing the number of pulses.

In the actinic image, such as the plan view illustration shown in FIG. 2A, the presence of a protrusion and/or the profile of the recessed surface may not be readily observable. Accordingly, embodiments may also include analyzing the fiducial 250 with other metrology tools. For example, atomic force microscopy (AFM) or scanning electron microscopy (SEM) may be used to quantify the profile of the fiducial 250. Examples of profiles of the fiducial 250 are shown in FIGS. 2B and 2C, in accordance with an embodiment.

Referring now to FIG. 2B, a plot of the profile of the fiducial 250 along line X-X′ in FIG. 2A is shown, in accordance with an embodiment. In an embodiment, the fiducial 250 may comprise a boundary 257 that separates the fiducial 250 from the capping layer 220 (or mirror layer). As shown, the thickness determined by the AFM begins to decreases at the boundary 257. The recessed surface 252 within the boundary 257 is a non-planar surface. In an embodiment, the recessed surface 252 may be referred to as a concave surface, a bowl surface, or the like.

Referring now to FIG. 2C, a plot of the profile of the fiducial along line X-X′ in FIG. 2A is shown, in accordance with an additional embodiment. In an embodiment, a protrusion 255 may extend out from the recessed surface 252. As noted above, protrusions 255 may be formed by increasing the energy of the femtosecond laser and/or increasing the number of pulses used to form the fiducial 250. In an embodiment, geometric characteristics (e.g., height, width, full width at half maximum, etc.) of the protrusion 255 may be quantified by the AFM. In an embodiment, the protrusion 255 may be substantially centered within the fiducial 250. In the illustrated embodiment, the protrusions 255 is shown as having a height that is greater than its width. However, it is to be appreciated that the protrusion 255 may also comprise a width that is equal to or greater than the height of the protrusion 255.

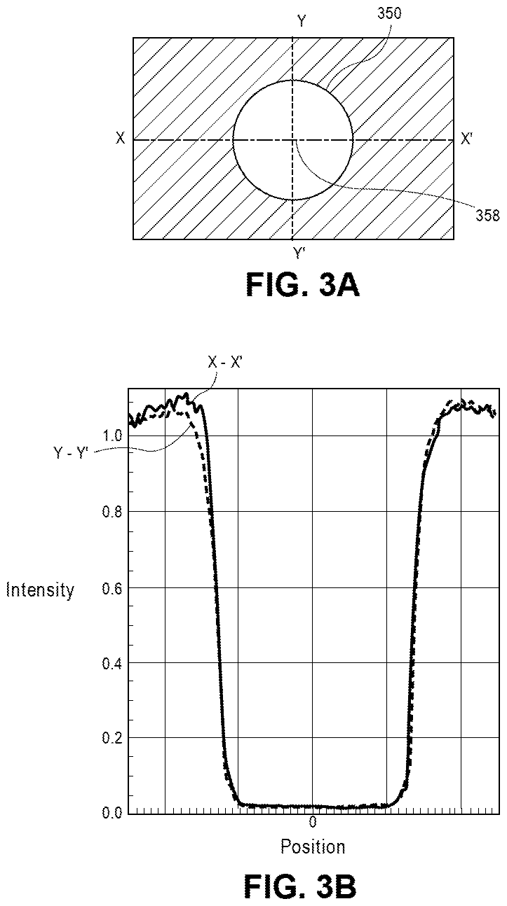

Referring now to FIGS. 3A and 3B, a plan view illustration of an actinic image of the fiducial 350 and a plot of intensities along lines X-X′ and Y-Y′ are shown, in accordance with an embodiment. In an embodiment, the intensity along lines X-X′ and Y-Y′ may be used to find a center point 358 of the fiducial 350. It will be appreciated to those skilled in the art that a plurality of image processing algorithms can be employed to determine the centroid of a given fiducial mark. As shown in FIG. 3B, plotting line scans of intensity in the X and Y directions shows a sharp drop (i.e., excellent normalized image log-slope (NILS)) in intensity. The intensity scan illustrated in FIG. 3B may then be processed to determine the centroid with a high degree of accuracy. In an embodiment, optimization of physical characteristics of the femtosecond fiducial marks in conjunction with alignment mark detection and processing algorithms (e.g., application of 2D grid matching calculation from a plurality of fiducial marks located in the appropriate sites within the peripheral pattern region of the mask) can yield an ultrahigh accuracy pattern alignment process that is necessary for mirror layer defect mitigation schemes.

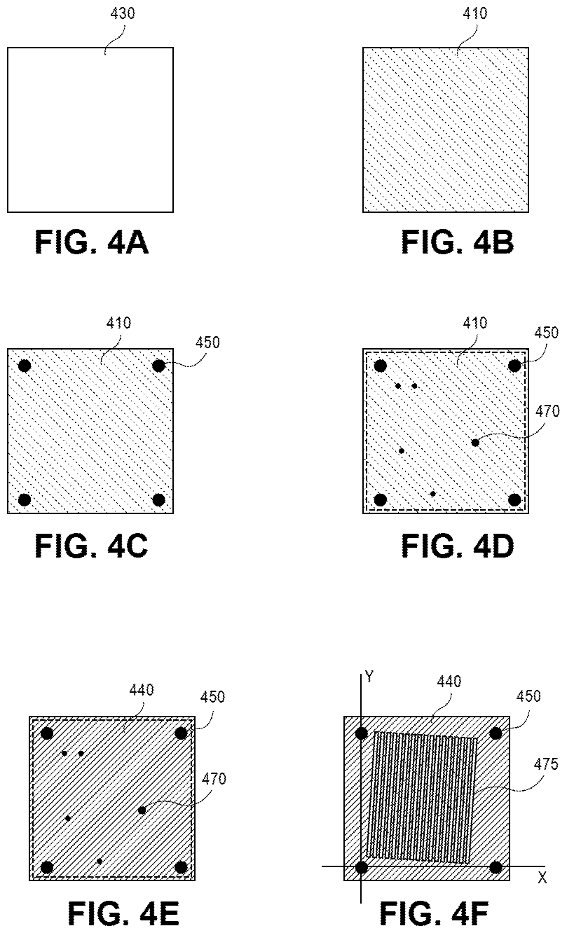

Referring now to FIGS. 4A-4F, a series of plan view illustrations that illustrate a process for forming and using fiducials formed with a femtosecond laser is shown, in accordance with an embodiment.

Referring now to FIG. 4A, a plan view illustration of a reticle substrate 430 is shown, in accordance with an embodiment. In an embodiment, the reticle substrate 430 may be a blank substrate (i.e., no fiducial marks are formed on the substrate). In an embodiment, the reticle substrate 430 may be any suitable low thermal expansion coefficient material, such as quartz or the like.

Referring now to FIG. 4B, a plan view illustration after a mirror layer 410 is formed over the substrate 430 is shown, in accordance with an embodiment. In an embodiment, the mirror layer 410 may comprise a plurality of alternating first mirror layers and second mirror layers. For example, the first mirror layers may comprise molybdenum and the second mirror layers may comprise silicon. While not illustrated, it is to be appreciated that a capping layer (e.g., ruthenium) may be formed over the mirror layer 410, as is known in the art.

Referring now to FIG. 4C, a plan view illustration after a plurality of fiducials 450 are formed into the mirror layer 410 is shown, in accordance with an embodiment. In an embodiment, the fiducials 450 may be formed with a femtosecond laser. In an embodiment, the fiducials 450 may be substantially circular. In an embodiment, the fiducials 450 may have a recessed surface similar to embodiments described above. In an additional embodiment, the fiducials 450 may comprise a protrusion (not shown) extending out from the recessed surface of the fiducials 450, similar to embodiments described above.

Referring now to FIG. 4D, a plan view illustration after the mirror layer 410 is inspected by one or more defect inspection tools is shown, in accordance with an embodiment. In an embodiment, the defect inspection tool may identify the location of defects 470 and determine a position of the defects 470 relative to the fiducials 450. In an embodiment, the defect inspection may include 13.5 nm inspection, 266 nm inspection, and the like. In FIG. 4D a dashed line around the fiducials 450 is shown to indicate that the area within the dashed line has been mapped to provide locations of the defects 470 relative to the fiducials 450.

Referring now to FIG. 4E, plan view illustration after an absorber layer 440 is formed over the mirror layer 410 is shown, in accordance with an embodiment. In an embodiment, the absorber layer 440 may comprise tantalum nitride, tantalum boron nitride, or any other suitable material that absorbs the EUV radiation. In an embodiment, the fiducials 450 and the defects 470 may be visible through the absorber layer 440.

Referring now to FIG. 4F, a plan view illustration after the absorber layer 440 is patterned to form an absorber pattern 475 is shown, in accordance with an embodiment. In an embodiment, the absorber layer 440 may be patterned by disposing a resist layer (not shown) over the absorber layer 440 and writing the mask pattern into the resist layer (e.g., with an electron-beam writer or the like). The portions of the absorber layer 440 not covered by the resist layer may be etched away to expose portions of the mirror layer 410.

In an embodiment, the absorber pattern 475 may be considered a shifted pattern. For example, the mask pattern 475 may be shifted in order to minimize the printing of defects (i.e., the mask pattern is shifted in order for as many of the defects as possible to be covered by the patterned absorber layer 475). In an embodiment, the electron-beam writer may be aligned with the fiducials 450 (as indicated by the X and Y axis in FIG. 4F). In an embodiment, the pattern may be shifted in the X-direction, the Y-direction, and/or rotated (e.g., 90, 180 or 270 degrees) in order to provide optimal defect mitigation. Optimal defect mitigation is defined as the pattern shifting solution (i.e., translation and rotation) which results in rendering the maximum number of printable defects non-printable by locating said defects partially or entirely under absorbing patterns.

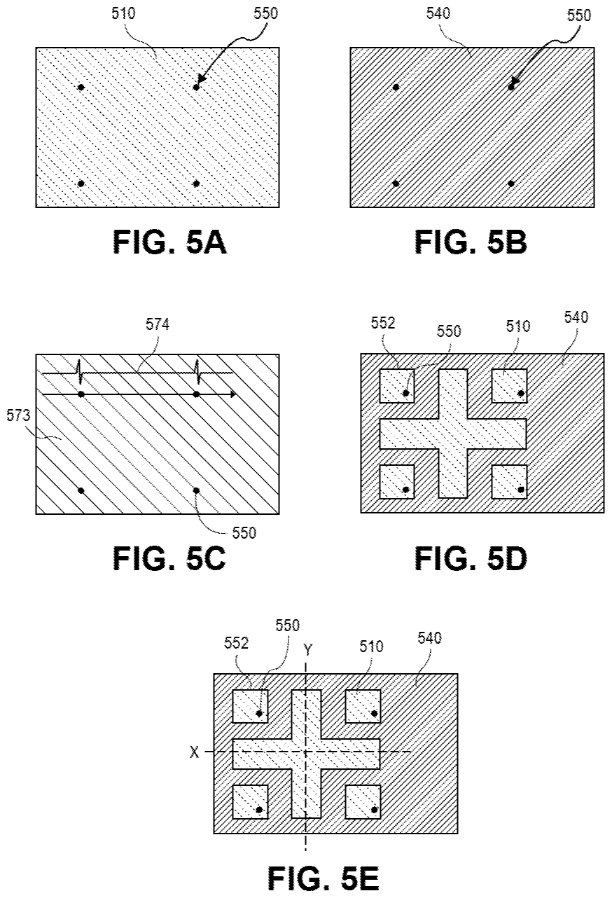

Referring now to FIGS. 5A-5E, a series of plan view illustrations that illustrate a process for forming and using femtosecond laser generated fiducials and secondary fiducials is shown, in accordance with an additional embodiment. Referring now to FIG. 5A, a plan view illustration of a plurality of fiducials 550 formed over mirror layer 510 is shown, in accordance with an embodiment. In an embodiment, the fiducials 550 may be formed with a femtosecond laser as described in greater detail above.

Referring now to FIG. 5B, a cross-sectional illustration after an absorber layer 540 is formed over the mirror layer 510 is shown, in accordance with an embodiment. In an embodiment, the absorber layer 540 may comprise tantalum nitride, tantalum boron nitride, or any other suitable material that absorbs the EUV radiation.

Referring now to FIG. 5C, a plan view illustration after a resist layer 573 is formed over the absorber layer 540 and the fiducials 550 are detected is shown, in accordance with an embodiment. In an embodiment, the fiducials 550 may be located with a scattered electron signal from the primary beam raster of an electron-beam writer. In order to illustrate the process, the electron beam signal 574 is superimposed over the plan view of the resist layer 573. It is to be appreciated that the fiducials 550 may be covered by both the absorbing layer (i.e., such absorber layer 440 in FIG. 4E, and absorber layer 540 in FIG. 5B) and a photoresist coating 573.

Referring now to FIG. 5D, a plan view illustration after secondary fiducials 552 are formed into the absorber layer 540 is shown, in accordance with an embodiment. In an embodiment, the electron-beam writer may be coarsely aligned with the fiducials 550 (i.e., using the location information obtained in FIG. 5C). The coarsely aligned electron-beam writer may then write the secondary fiducials 552. In an embodiment, the exposed absorber material is patterned to expose the mirror layer 510 and the first fiducials 550. For example, the secondary fiducials 552 may form openings through the absorber layer 540 that expose the fiducials 550. After the secondary fiducials 552 are formed, the resist layer 573 may be removed to expose the unpatterned portions of the absorber layer 540.

Referring now to FIG. 5E, a plan view illustration after the relationship between the first fiducials 550 and the second fiducials 552 is determined is shown, in accordance with an embodiment. In an embodiment, the region may be imaged (e.g., using actinic image metrology (AIMS) or an atomic force microscope (AFM) with a high precision interferometric stage (i.e., an AFM with sufficient lateral feature resolution capability)). The resulting image may then be post-processed to determine offsets (e.g., rotational, translational, etc.) of the first fiducials 550 with respect to the secondary fiducials 552. The offset information may then be applied to the mirror layer blank inspection defect information, and the mirror layer defect mitigation is implemented in accordance with embodiments described above (e.g., a best pattern shifting solution is calculated and applied to minimize the printing of defects in the mirror layer).

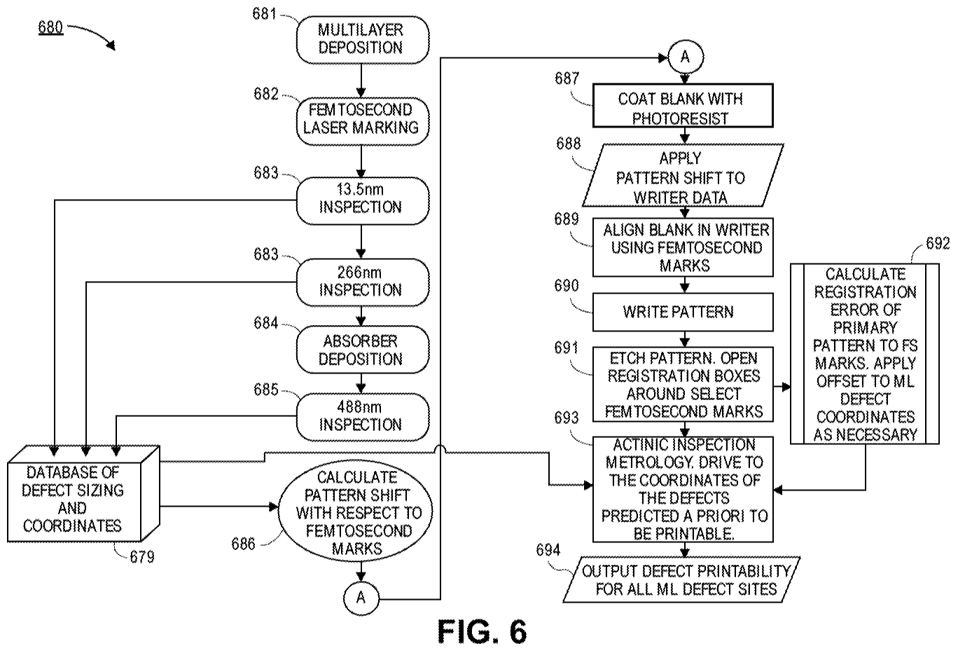

Referring now to FIG. 6, a process flow diagram for using femtosecond laser generated fiducials is illustrated, in accordance with an embodiment. While FIG. 6 explicitly illustrates various processing operations, it is to be appreciated that additional processing operations (or fewer processing operations) may be implemented in accordance with various embodiments.

In an embodiment, process 680 may begin with operation 681 that comprises forming a multilayer mirror over a substrate. For example, the multilayer mirror may be any suitable mirror layer, such as those described above. In an embodiment, the multilayer mirror may comprise alternating layers of first and second mirror layers (e.g., molybdenum and silicon).

In an embodiment, process 680 may continue with operation 682 that comprises forming fiducial marks in the mirror layer. In an embodiment, the fiducials may be formed with a femtosecond laser, as described above. In such an embodiment, the fiducials may comprise a recessed surface, and may optionally comprise a protrusion up from the recessed surface.

In an embodiment, process 680 may further comprise one or more inspection operations 683. For example, in FIG. 6 a first inspection (13.5 nm inspection) and a second inspection (266 nm inspection) are implemented. However, it is to be appreciated that fewer or more inspections or other metrology may be implemented. In an embodiment, the one or more inspections may generate information on defect size, shape, area and printing characteristics as a function of focus and dose and centroid locations (relative to the fiducials). In an embodiment, the defect information generated by the inspections may be stored in a defect database 679. In this embodiment, the said defect information can be post-processed to determine the nature of a defect (e.g., to determine if the defect is a, so-called, phase defect or amplitude defect). Stored defect information can be used to calculate the best solution for repair of a given site.

In an embodiment, process 680 may further comprise operation 684 that comprises forming an absorber layer over the mirror layer. In an embodiment the absorber layer may comprise tantalum nitride, tantalum boron nitride, or any other suitable material that absorbs the EUV radiation. In an embodiment, process 680 may then proceed with one or more inspections 685 of the absorber layer. For example, absorber layer may be inspected with a 488 nm inspection tool or the like. In an embodiment, defect information from the inspection 685 may be stored in the defect database 679.

Referring now to operation 686 of process 680, a pattern shift with respect to the fiducials may be calculated using information from the defect database 679. In an embodiment, the process 680 may then continue with operation 687 that comprises forming a blank resist over the absorber layer. In an embodiment, process 680 may then comprise operation 688 that comprises applying the pattern shift to the writer data. Thereafter, process 680 may include operation 689 that comprises aligning the blank in the e-beam writer using the fiducials. In an embodiment, process 680 may then comprise operation 690 that comprises writing the pattern into the blank. Registration data can be used to determine which defects may possibly be printable and thus require additional (e.g., actinic) inspection and possible repair.

Referring now to operation 691, process 680 may comprise etching the pattern into the absorber layer. In an embodiment, operation 691 may include opening registration boxes around one or more of the fiducials. In an embodiment, the registration boxes may then be used to calculate registration error of the primary pattern to the fiducial marks. In such embodiments the offset may be applied to the mirror layer defect coordinates, as necessary, as shown in operation 692.

Referring now to operation 693, process 680 may comprise implementing actinic inspection metrology. In an embodiment, the actinic inspection metrology may use coordinates of the defects relative to fiducials obtained from the defect database 679. In an embodiment, this allows for improved throughput since the defects are predicted to be present and inspection of those defects may be quickly implemented since the inspection or imaging instrument (e.g. actinic inspection metrology, atomic force microscope, scanning electron microscope, etc.) can use the coordinates to quickly drive to the precise location. Mathematical comparison of the known defective site to either a reference site or to a pattern database can be conducted to quantify the printability of a given defect.

Referring now to operation 694, process 680 may further comprise outputting defect printability data for all mirror layer defect sites. Particularly, the prediction of which defects will print may be used to implement an improved repair process in order to mitigate the printed defects.

The above description of illustrated implementations of embodiments of the disclosure, including what is described in the Abstract, is not intended to be exhaustive or to limit the disclosure to the precise forms disclosed. While specific implementations of, and examples for, the disclosure are described herein for illustrative purposes, various equivalent modifications are possible within the scope of the disclosure, as those skilled in the relevant art will recognize.

These modifications may be made to the disclosure in light of the above detailed description. The terms used in the following claims should not be construed to limit the disclosure to the specific implementations disclosed in the specification and the claims. Rather, the scope of the disclosure is to be determined entirely by the following claims, which are to be construed in accordance with established doctrines of claim interpretation.

Example 1: a reticle, comprising: a substrate; a mirror layer over the substrate, wherein the mirror layer comprises alternating layers of a first mirror layer and a second mirror layer; a fiducial formed into the mirror layer, wherein the fiducial comprises constituents of the first mirror layer and the second mirror layer; and an absorber layer over the mirror layer.

Example 2: the reticle of Example 1, wherein the fiducial comprises no distinguishable alternating layers of the first mirror layer and the second mirror layer.

Example 3: the reticle of Example 1 or Example 2, wherein the fiducial comprises a recessed surface relative to an uppermost surface of the mirror layer.

Example 4: the reticle of Examples 1-3, wherein the recessed surface is a concave surface.

Example 5: the reticle of Examples 1-4, wherein the fiducial comprises a protrusion up from the recessed surface.

Example 6: the reticle of Examples 1-5, wherein the protrusion is substantially centered within the fiducial.

Example 7: the reticle of Examples 1-6, wherein the protrusion has a point that is coplanar with or below a surface of the mirror layer.

Example 8: the reticle of Examples 1-7, wherein the fiducial is substantially circular.

Example 9: the reticle of Examples 1-8, wherein a diameter of the fiducial is between approximately 0.25 μm and approximately 5 μm.

Example 10: the reticle of Examples 1-9, wherein the first mirror layer is silicon and the second mirror layer is molybdenum.

Example 11: the reticle of Examples 1-10, further comprising a capping layer between the mirror layer and the absorber layer, wherein the fiducial is formed into the mirror layer and the capping layer.

Example 12: the reticle of Examples 1-11, wherein the fiducial is formed with a femtosecond pulsed laser.

Example 13: the reticle of Examples 1-12, further comprising a plurality of fiducials.

Example 14: a method of forming a fiducial for an extreme ultra violet (EUV) reticle, comprising: providing an EUV reticle, wherein the EUV reticle comprises: a substrate; and a mirror layer over the substrate, wherein the mirror layer comprises a plurality of alternating layers of a first mirror layer and a second mirror layer; and irradiating the mirror layer with femtosecond laser radiation to form a fiducial in the mirror layer.

Example 15: the method of Example 14, wherein the laser radiation locally melts portions of the mirror layer to form the fiducial.

Example 16: the method of Example 14 or Example 15, wherein the first mirror layer and the second mirror layer in the fiducial area are melted and solidify as an amorphous alloy comprising constituents of the first mirror layer and the second mirror layer.

Example 17: the method of Examples 14-16, wherein the laser radiation is focused to a depth within the mirror layer.

Example 18: the method of Examples 14-17, wherein the laser radiation is focused on a surface of the substrate below the mirror layer.

Example 19: the method of Examples 14-18, wherein the energy of the laser radiation is chosen to provide a fiducial with a protrusion.

Example 20: the method of Examples 14-19, wherein the femtosecond laser is pulsed a number of times to provide a fiducial with a protrusion.

Example 21: the method of Examples 14-20, wherein a surface of the fiducial is recessed from a top surface of the mirror layer, wherein the recessed surface is concave.

Example 22: the method of Examples 14-21, wherein the fiducial further comprises a protrusion extending out from the recessed surface of the fiducial.

Example 23: a method of using fiducials to fabricate an extreme ultraviolet (EUV) reticle, comprising: forming a mirror layer over a substrate, wherein the mirror layer comprises a plurality of alternating layers of a first mirror layer and a second mirror layer; forming a plurality of fiducials in the mirror layer, wherein the fiducials are formed with a femtosecond laser; inspecting the mirror layer, wherein inspecting the mirror layer comprises detecting defects in the mirror layer and recording positions of the defects relative to the fiducials; forming an absorber layer over the mirror layer; calculating an absorber layer pattern shift that minimizes the printing of the defects; and patterning the absorber layer with the absorber layer pattern shift.

Example 24: the method of Example 23, further comprising: forming an opening around the fiducials through the absorber layer to expose the fiducials; and calculating a registration error of the fiducials relative to the absorber layer pattern shift.

Example 25: the method of Example 23 or Example 24, further comprising: determining a location of defects that will not be covered by the absorber layer pattern shift; and repairing the printed defects after the absorber layer is patterned.

What is claimed is:

1. A reticle, comprising:
a substrate;
a mirror layer over the substrate, wherein the mirror layer comprises alternating layers of a first mirror layer and a second mirror layer;
a fiducial formed into the mirror layer, wherein the fiducial comprises constituents of the first mirror layer and the second mirror layer; and
an absorber layer over the mirror layer.

2. The reticle of claim 1, wherein the fiducial comprises no distinguishable alternating layers of the first mirror layer and the second mirror layer.

3. The reticle of claim 1, wherein the fiducial comprises a recessed surface relative to an uppermost surface of the mirror layer.

4. The reticle of claim 3, wherein the recessed surface is a concave surface.

5. The reticle of claim 3, wherein the fiducial comprises a protrusion up from the recessed surface.

6. The reticle of claim 5, wherein the protrusion is substantially centered within the fiducial.

7. The reticle of claim 5, wherein the protrusion has a point that is coplanar with or below a surface of the mirror layer.

8. The reticle of claim 1, wherein the fiducial is substantially circular.

9. The reticle of claim 8, wherein a diameter of the fiducial is between approximately 0.25 μm and approximately 5 μm.

10. The reticle of claim 1, wherein the first mirror layer is silicon and the second mirror layer is molybdenum.

11. The reticle of claim 1, further comprising a capping layer between the mirror layer and the absorber layer, wherein the fiducial is formed into the mirror layer and the capping layer.

12. The reticle of claim 1, wherein the fiducial is formed with a femtosecond pulsed laser.

13. The reticle of claim 1, further comprising a plurality of fiducials.

14. A method of forming a fiducial for an extreme ultra violet (EUV) reticle, comprising:
providing an EUV reticle, wherein the EUV reticle comprises:
a substrate; and
a mirror layer over the substrate, wherein the mirror layer comprises a plurality of alternating layers of a first mirror layer and a second mirror layer; and
irradiating the mirror layer with femtosecond laser radiation to form a fiducial in the mirror layer.

15. The method of claim 14, wherein the laser radiation locally melts portions of the mirror layer to form the fiducial.

16. The method of claim 15, wherein the first mirror layer and the second mirror layer in the fiducial area are melted and solidify as an amorphous alloy comprising constituents of the first mirror layer and the second mirror layer.

17. The method of claim 14, wherein the laser radiation is focused to a depth within the mirror layer.

18. The method of claim 14, wherein the laser radiation is focused on a surface of the substrate below the mirror layer.

19. The method of claim 14, wherein the energy of the laser radiation is chosen to provide a fiducial with a protrusion.

20. The method of claim 14, wherein the femtosecond laser is pulsed a number of times to provide a fiducial with a protrusion.

21. The method of claim 14, wherein a surface of the fiducial is recessed from a top surface of the mirror layer, wherein the recessed surface is concave.

22. The method of claim 21, wherein the fiducial further comprises a protrusion extending out from the recessed surface of the fiducial.

23. A method of using fiducials to fabricate an extreme ultraviolet (EUV) reticle, comprising:
forming a mirror layer over a substrate, wherein the mirror layer comprises a plurality of alternating layers of a first mirror layer and a second mirror layer;
forming a plurality of fiducials in the mirror layer, wherein the fiducials are formed with a femtosecond laser;
inspecting the mirror layer, wherein inspecting the mirror layer comprises detecting defects in the mirror layer and recording positions of the defects relative to the fiducials;
forming an absorber layer over the mirror layer;
calculating an absorber layer pattern shift that minimizes the printing of the defects; and
patterning the absorber layer with the absorber layer pattern shift.

24. The method of claim 23, further comprising:
forming an opening around the fiducials through the absorber layer to expose the fiducials; and
calculating a registration error of the fiducials relative to the absorber layer pattern shift.

25. The method of claim 23, further comprising:
determining a location of defects that will not be covered by the absorber layer pattern shift; and
repairing the printed defects after the absorber layer is patterned.
